(19) United States
(12) Patent Application Publication
(10) Pub. No.: US 2015/0250078 A1
(43) Pub. Date: Sep. 3, 2015

(54) TRANSPARENT CONDUCTIVE FILM

(71) Applicant: NITTO DENKO CORPORATION, Ibaraki-shi, Osaka (JP)

(72) Inventors: Shouichi Matsuda, Ibaraki-shi (JP); Hiroshi Tomohisa, Ibaraki-shi (JP); Kanji Nishida, Ibaraki-shi (JP)

(73) Assignee: NITTO DENKO CORPORATION, Ibaraki-shi, Osaka (JP)

(21) Appl. No.: 14/436,691

(22) PCT Filed: Nov. 1, 2013
(86) PCT No.: PCT/JP2013/079696

§ 371 Date: Apr. 17, 2015

(30) Foreign Application Priority Data
Nov. 2, 2012 (JP) 2012-242713
May 27, 2013 (JP) 2013-110801

(51) Int. Cl. H05K 9/00; H01L 27/32; H01L 51/52; G02F 1/1333

(52) U.S. Cl. CPC H05K 9/009; G02F 1/13338; H01L 27/323; H01L 51/5253; H01L 51/5293; H01L 2251/558

(57) ABSTRACT

There is provided a transparent conductive film that is simply and easily produced, has a high transmittance and high conductivity, and can suppress the occurrence of a rainbow-like patchy pattern. A transparent conductive film of the present invention includes: a transparent base material; and a transparent conductive layer formed on the transparent base material, the transparent conductive film having a total light transmittance of 80% or more, wherein: the transparent base material has an absolute value of a thickness direction retardation of 100 nm or less; and the transparent conductive layer contains a metal nanowire or a metal mesh.

### TECHNICAL FIELD

The present invention relates to a transparent conductive film.

### BACKGROUND ART

A transparent conductive film has heretofore been used in, for example, an electrode for an electronic device part such as a touch panel or an electromagnetic wave shield for blocking an electromagnetic wave responsible for the malfunction of an electronic device. It has been known that the transparent conductive film is obtained through the formation of a metal oxide layer such as an indium-tin composite oxide (ITO) on a transparent resin film by a sputtering method. However, the production of the transparent conductive film by the sputtering method involves a problem in that a large-scale facility is needed and hence a cost becomes high. In addition, the production involves a problem in that it is difficult to produce a transparent conductive film having a large width. Further, the transparent conductive film obtained by the sputtering method involves a problem in that its light transmittance is low.

A method involving forming a conductive layer constituted of, for example, a metal nanowire or a metal mesh on a polyethylene terephthalate (PET) base material has been proposed as a method of solving the problems of the sputtering method. For example, Patent Literature 1 proposes a method involving forming a layer containing a silver nanowire on the PET base material. A transparent conductive film obtained by the method has a high transmittance because the layer containing the silver nanowire has an opening portion. However, the PET to be used as the base material has an extremely large retardation because the PET requires a stretching treatment for obtaining practical mechanical strength. When the transparent conductive film obtained by using such PET base material is used by being incorporated into, for example, a liquid crystal display, a rainbow-like patchy pattern (hereinafter sometimes referred to as “rainbow patch”) occurs. Such phenomenon becomes a problem particularly when a transparent conductive film having a high transmittance (such as a transparent conductive film containing a metal nanowire (silver nanowire), a metal mesh, or the like as described above) is used, i.e., when the quantity of light to be output from the transparent conductive film is large. In addition, the rainbow patch is remarkably observed in viewing from an oblique direction, and hence the occurrence of the rainbow patch becomes a problem particularly in a large display an end portion of the screen of which is to be viewed from an oblique direction.

### CITATION LIST

### Patent Literature

[PTL 1] JP 2009-505358 A

### SUMMARY OF INVENTION

### Technical Problem

The present invention has been made to solve the problems, and an object of the present invention is to provide a transparent conductive film that is simply and easily produced, has a high transmittance and high conductivity, and can suppress the occurrence of a rainbow-like patchy pattern.

### Solution to Problem

A transparent conductive film of the present invention includes: a transparent base material; and a transparent conductive layer formed on the transparent base material, the transparent conductive film having a total light transmittance of 80% or more, wherein: the transparent base material has an absolute value of a thickness direction retardation of 100 nm or less; and the transparent conductive layer contains a metal nanowire or a metal mesh.

In one embodiment of the present invention, the thickness direction retardation of the transparent base material is 50 nm or less.

In one embodiment of the present invention, the transparent base material has an in-plane retardation of 10 nm or less.

In one embodiment of the present invention, the transparent base material contains a cycloolefin-based resin.

In one embodiment of the present invention, the transparent base material contains an acrylic resin.

In one embodiment of the present invention, the metal nanowire comprises a silver nanowire.

According to another aspect of the present invention, there is provided a touch panel. The touch panel includes the transparent conductive film.

According to another aspect of the present invention, there is provided an electromagnetic wave shield. The electromagnetic wave shield includes the transparent conductive film.

According to another aspect of the present invention, there is provided a liquid crystal display element. The liquid crystal display element includes the touch panel and/or the electromagnetic wave shield.

According to another aspect of the present invention, there is provided an organic electroluminescence display apparatus. The organic electroluminescence display apparatus includes the touch panel, a polarizing plate, and an organic electroluminescence element in the stated order from a viewer side.

In one embodiment of the present invention, the organic electroluminescence display apparatus further includes the electromagnetic wave shield between the touch panel and the polarizing plate.

In one embodiment of the present invention, the organic electroluminescence display apparatus includes the electromagnetic wave shield, a polarizing plate, and an organic electroluminescence element in the stated order from a viewer side.

### Advantageous Effects of Invention

According to the present invention, the transparent conductive layer containing the metal nanowire or the metal mesh is formed on the transparent base material having a small absolute value of a thickness direction retardation, and hence the transparent conductive film that has a high transmittance and high conductivity, and can suppress the occurrence of a rainbow-like patchy pattern can be provided. The transparent conductive film of the present invention can be simply and easily produced because the transparent conductive layer can be formed by application.

### BRIEF DESCRIPTION OF DRAWINGS

FIG. 1 is a schematic sectional view of a transparent conductive film according to a preferred embodiment of the present invention.

FIG. 2 is a schematic sectional view of a liquid crystal display element according to one embodiment of the present invention.

FIG. 3 is a schematic sectional view of a liquid crystal display element according to one embodiment of the present invention.

FIG. 4 is a schematic sectional view of an organic electroluminescence display apparatus according to one embodiment of the present invention.

FIG. 5 is a schematic sectional view of an organic electroluminescence display apparatus according to one embodiment of the present invention.

### DESCRIPTION OF EMBODIMENTS

A. Entire Construction of Transparent Conductive Film

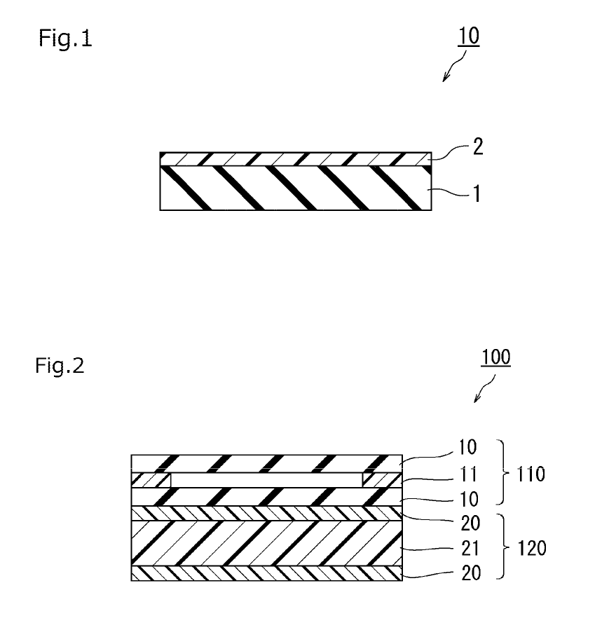

FIG. 1 is a schematic sectional view of a transparent conductive film according to a preferred embodiment of the present invention. As illustrated in FIG. 1, a transparent conductive film 10 of the present invention includes a transparent base material 1 and a transparent conductive layer 2 formed on the transparent base material 1. The transparent conductive layer 2 contains a metal nanowire or a metal mesh.

The total light transmittance of the transparent conductive film of the present invention is preferably 80% or more, more preferably 85% or more, particularly preferably 90% or more. In the present invention, the transparent conductive layer containing the metal nanowire or the metal mesh is provided, and hence a transparent conductive film having a high total light transmittance can be obtained. In addition, the transparent conductive film of the present invention includes a transparent base material having a small thickness direction retardation. Accordingly, even when the transmittance is high as described above, i.e., even when the quantity of light to be output from the transparent conductive film is large, the film can suppress a rainbow patch. One of the effects of the present invention is that compatibility between the high light transmittance and the suppression of the rainbow patch has been achieved.

The surface resistance value of the transparent conductive film of the present invention is preferably from 0.1Ω/□ to 1,000Ω/□, more preferably from 0.5Ω/□ to 500Ω/□, particularly preferably from 1Ω/□ to 250Ω/□. In the present invention, the transparent conductive layer containing the metal nanowire or the metal mesh is provided, and hence a transparent conductive film having a small surface resistance value can be obtained. In addition, as described above, excellent conductivity can be expressed with a small amount of a metal while the surface resistance value is kept small, and hence a transparent conductive film having a high light transmittance can be obtained.

B. Transparent Base Material

The absolute value of a thickness direction retardation Rth of the transparent base material is 100 nm or less, preferably 75 nm or less, more preferably 50 nm or less, particularly preferably 10 nm or less, most preferably 5 nm or less. It should be noted that the thickness direction retardation Rth as used herein refers to the thickness direction retardation value of the transparent base material at 23° C. and a wavelength of 545.6 nm. The Rth is determined from the equation “Rth=(nx−nz)×d” where nx represents a refractive index in the direction in which an in-plane refractive index becomes maximum (i.e., a slow axis direction), nz represents a thickness direction refractive index, and d (nm) represents the thickness of the transparent base material.

An in-plane retardation Re of the transparent base material is preferably 10 nm or less, more preferably 5 nm or less, still more preferably from 0 nm to 2 nm. It should be noted that the in-plane retardation Re as used herein refers to the in-plane retardation value of the transparent base material at 23° C. and a wavelength of 545.6 nm. The Re is determined from the equation “Re=(nx−ny)×d” where nx represents the refractive index in the direction in which the in-plane refractive index becomes maximum (i.e., the slow axis direction), ny represents a refractive index in a direction perpendicular to the slow axis in a plane (i.e., a fast axis direction), and d (nm) represents the thickness of an optical film.

The transparent conductive film of the present invention can suppress a rainbow patch by using a transparent base material having a small thickness direction retardation as described above. In addition, a suppressing effect on the rainbow patch is made additionally significant by using a transparent base material both the thickness direction retardation and in-plane retardation of which are small. The use of a transparent base material having a low retardation may reduce the optical path difference of light that passes through the transparent base material in an oblique direction to exhibit such effect as described above. In addition, such effect becomes additionally significant when light that passes through the transparent base material is elliptically polarized light.

The thickness of the transparent base material is preferably from 20 μm to 200 μm, more preferably from 30 μm to 150 μm. When the thickness falls within such range, a transparent base material having a small retardation can be obtained.

The total light transmittance of the transparent base material is preferably 80% or more, more preferably 85% or more, still more preferably 90% or more.

Any appropriate material can be used as a material constituting the transparent base material. Specifically, for example, a polymer base material such as a film or a plastic base material is preferably used. This is because the smoothness of the transparent base material and its wettability to a composition for forming a transparent conductive layer become excellent, and its productivity can be significantly improved by continuous production with a roll. A material capable of expressing a thickness direction retardation Rth in the above-mentioned range is preferably used.

The material constituting the transparent base material is typically a polymer film using a thermoplastic resin as a main component. Examples of the thermoplastic resin include: cycloolefin-based resins such as polynorbornene; acrylic resins; and low-retardation polycarbonate resins. Of those, a cycloolefin-based resin or an acrylic resin is preferred. The use of such resin can provide a transparent base material having a small retardation. In addition, such resin is excellent in, for example, transparency, mechanical strength, thermal stability, and moisture barrier property. One kind of the thermoplastic resins may be used alone, or two or more kinds thereof may be used in combination.

The polynorbornene refers to a (co)polymer obtained by using a norbornene-based monomer having a norbornene ring as part or the entirety of starting raw materials (monomers). Examples of the norbornene-based monomer include: norbornene and an alkyl and/or alkylidene substitution product thereof such as 5-methyl-2-norbornene, 5-dimethyl-2-norbornene, 5-ethyl-2-norbornene, 5-butyl-2-norbornene, or 5-ethylidene-2-norbornene, and a substitution product thereof with a polar group such as a halogen; dicyclopentadiene; 2,3-dihydrodicyclopentadiene; and dimethanooctahydronaphthalene, an alkyl and/or alkylidene substitution product thereof, and a substitution product thereof with a polar group such as a halogen, and a trimer and tetramer of cyclopentadiene such as 4,9:5,8-dimethano-3a,4,4a,5,8,8a,9,9a-octahydro-1H-benzoindene and 4,11:5,10:6,9-trimethano-3a,4,4a,5,5a,6,9,9a,10,10a,11,11a-dodecahydro-1H-cyclopentaanthracene.

Various products are commercially available as the polynorbornene. Specific examples thereof include: products available under the trade names “ZEONEX” and “ZEONOR” from neon Corporation; a product available under the trade name “Arton” from JSR Corporation; a product available under the trade name “TOPAS” from TICONA; and a product available under the trade name “APEL” from Mitsui Chemicals, Inc.

The acrylic resin refers to a resin having a repeating unit derived from a (meth)acrylate ((meth)acrylate unit) and/or a repeating unit derived from (meth)acrylic acid ((meth)acrylic acid unit). The acrylic resin may have a constituent unit derived from a derivative of a (meth)acrylate or (meth)acrylic acid.

In the acrylic resin, the total content of the (meth)acrylate unit, the (meth)acrylic acid unit, and the constituent unit derived from a derivative of a (meth)acrylate or (meth)acrylic acid is preferably 50 wt % or more, more preferably from 60 wt % to 100 wt %, particularly preferably from 70 wt % to 90 wt % with respect to all constituent units constituting the acrylic resin. When the total content falls within such range, a transparent base material having a low retardation can be obtained.

The acrylic resin may have a ring structure on its main chain. The presence of the ring structure can increase the glass transition temperature of the acrylic resin while suppressing an increase in its retardation. Examples of the ring structure include a lactone ring structure, a glutaric anhydride structure, a glutarimide structure, an N-substituted maleimide structure, and a maleic anhydride structure.

The lactone ring structure can adopt any appropriate structure. The lactone ring structure is preferably a four- to eight-membered ring, more preferably a five-membered ring or a six-membered ring, still more preferably a six-membered ring. A six-membered lactone ring structure is, for example, a lactone ring structure represented by the following general formula (1).

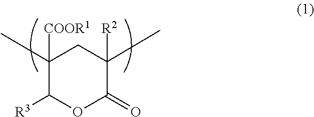

In the general formula (1), R¹, R², and R³ each independently represent a hydrogen atom, a linear or branched alkyl group having 1 to 20 carbon atoms, an unsaturated aliphatic hydrocarbon group having 1 to 20 carbon atoms, or an aromatic hydrocarbon group having 1 to 20 carbon atoms. The alkyl group, the unsaturated aliphatic hydrocarbon group, and the aromatic hydrocarbon group may each have a substituent such as a hydroxyl group, a carboxyl group, an ether group, or an ester group.

The glutaric anhydride structure is, for example, a glutaric anhydride structure represented by the following general formula (2). The glutaric anhydride structure can be obtained by, for example, subjecting a copolymer of a (meth)acrylate and (meth)acrylic acid to intramolecular dealcoholization cyclization condensation.

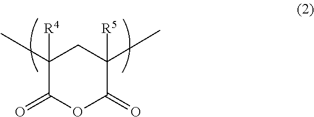

In the general formula (2), R⁴ and R⁵ each independently represent a hydrogen atom or a methyl group.

The glutarimide structure is, for example, a glutarimide structure represented by the following general formula (3). The glutarimide structure can be obtained by, for example, imidizing a (meth)acrylate polymer with an imidizing agent such as methylamine.

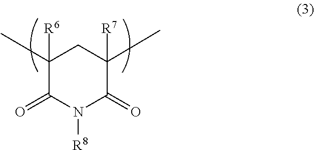

In the general formula (3), R⁶ and R⁷ each independently represent a hydrogen atom, or a linear or branched alkyl group having 1 to 8 carbon atoms, preferably a hydrogen atom or a methyl group. R⁸ represents a hydrogen atom, a linear alkyl group having 1 to 18 carbon atoms, a cycloalkyl group having 3 to 12 carbon atoms, or an aryl group having 6 to 10 carbon atoms, preferably a linear alkyl group having 1 to 6 carbon atoms, a cyclopentyl group, a cyclohexyl group, or a phenyl group.

In one embodiment, the acrylic resin has a glutarimide structure represented by the following general formula (4) and a methyl methacrylate unit.

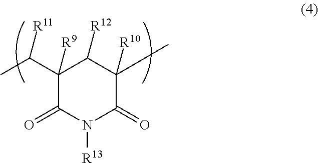

In the general formula (4), R⁹ to R¹² each independently represent a hydrogen atom, or a linear or branched alkyl group having 1 to 8 carbon atoms. R¹³ represents a linear or branched alkyl group having 1 to 18 carbon atoms, a cycloalkyl group having 3 to 12 carbon atoms, or an aryl group having 6 to 10 carbon atoms.

The N-substituted maleimide structure is, for example, an N-substituted maleimide structure represented by the following general formula (5). An acrylic resin having the N-substituted maleimide structure on its main chain can be obtained by, for example, copolymerizing an N-substituted maleimide and a (meth)acrylate.

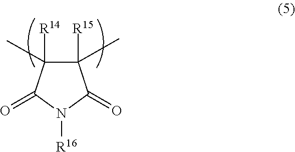

In the general formula (5), R¹⁴ and R¹⁵ each independently represent a hydrogen atom or a methyl group, and R¹⁶ represents a hydrogen atom, a linear alkyl group having 1 to 6 carbon atoms, a cyclopentyl group, a cyclohexyl group, or a phenyl group.

The maleic anhydride structure is, for example, a maleic anhydride structure represented by the following general formula (6). An acrylic resin having the maleic anhydride structure on its main chain can be obtained by, for example, copolymerizing maleic anhydride and a (meth)acrylate.

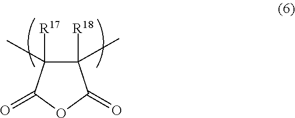

In the general formula (6), R¹⁷ and R¹⁸ each independently represent a hydrogen atom or a methyl group.

The acrylic resin may have any other constituent unit. Examples of the other constituent unit include constituent units derived from monomers such as styrene, vinyltoluene, α-methylstyrene, acrylonitrile, methyl vinyl ketone, ethylene, propylene, vinyl acetate, methallyl alcohol, allyl alcohol, 2-hydroxymethyl-1-butene, α-hydroxymethylstyrene, α-hydroxyethylstyrene, a 2-(hydroxyalkyl)acrylate such as methyl 2-(hydroxyethyl) acrylate, and a 2-(hydroxyalkyl) acrylic acid such as 2-(hydroxyethyl)acrylic acid.

In addition to the acrylic resins exemplified above, specific examples of the acrylic resin also include acrylic resins disclosed in JP 2004-168882 A, JP 2007-261265 A, JP 2007-262399 A, JP 2007-297615 A, JP 2009-039935 A, JP 2009-052021 A, and JP 2010-284840 A.

The glass transition temperature of the material constituting the transparent base material is preferably from 100° C. to 200° C., more preferably from 110° C. to 150° C., particularly preferably from 110° C. to 140° C. When the glass transition temperature falls within such range, a transparent conductive film excellent in heat resistance can be obtained.

The transparent base material may further contain any appropriate additive as required. Specific examples of the additive include a plasticizer, a heat stabilizer, a light stabilizer, a lubricant, an antioxidant, a UV absorber, a flame retardant, a coloring agent, an antistatic agent, a compatibilizer, a cross-linking agent, and a thickener. The kind and amount of the additive to be used may be appropriately set depending on purposes.

Any appropriate molding method is employed as a method of obtaining the transparent base material, and a proper method can be appropriately selected from, for example, a compression molding method, a transfer molding method, an injection molding method, an extrusion molding method, a blow molding method, a powder molding method, a FRP molding method, and a solvent casting method. Of those production methods, an extrusion molding method or a solvent casting method is preferably employed. This is because the smoothness of the transparent base material to be obtained is improved and hence good optical uniformity can be obtained. Molding conditions can be appropriately set depending on, for example, the composition and kind of the resin to be used.

The transparent base material may be subjected to various surface treatments as required. Any appropriate method is adopted for such surface treatment depending on purposes. Examples thereof include a low-pressure plasma treatment, an ultraviolet irradiation treatment, a corona treatment, a flame treatment, and acid and alkali treatments. In one embodiment, the surface of the transparent base material is hydrophilized by subjecting the transparent base material to a surface treatment. When the transparent base material is hydrophilized, processability upon application of a composition for forming a transparent conductive layer prepared with an aqueous solvent becomes excellent. In addition, a transparent conductive film excellent in adhesiveness between the transparent base material and the transparent conductive layer can be obtained.

C. Transparent Conductive Layer

The transparent conductive layer contains a metal nanowire or a metal mesh.

(Metal Nanowire)

The metal nanowire refers to a conductive substance that uses a metal as a material, has a needle- or thread-like shape, and has a diameter of the order of nanometers. The metal nanowire may be linear or may be curved. When a transparent conductive layer constituted of the metal nanowire is used, the metal nanowire is formed into a network shape. Accordingly, even when a small amount of the metal nanowire is used, a good electrical conduction path can be formed and hence a transparent conductive film having a small electrical resistance can be obtained. Further, the metal nanowire is formed into a network shape, and hence an opening portion is formed in a gap of the network. As a result, a transparent conductive film having a high light transmittance can be obtained.

A ratio (aspect ratio: L/d) between a thickness d and length L of the metal nanowire is preferably from 10 to 100,000, more preferably from 50 to 100,000, particularly preferably from 100 to 10,000. When a metal nanowire having such large aspect ratio as described above is used, the metal nanowire satisfactorily intersects with itself and hence high conductivity can be expressed with a small amount of the metal nanowire. As a result, a transparent conductive film having a high light transmittance can be obtained. It should be noted that the term “thickness of the metal nanowire” as used herein has the following meanings: when a section of the metal nanowire has a circular shape, the term means the diameter of the circle; when the section has an elliptical shape, the term means the short diameter of the ellipse; and when the section has a polygonal shape, the term means the longest diagonal of the polygon. The thickness and length of the metal nanowire can be observed with a scanning electron microscope or a transmission electron microscope.

The thickness of the metal nanowire is preferably less than 500 nm, more preferably less than 200 nm, particularly preferably from 10 nm to 100 nm, most preferably from 10 nm to 50 nm. When the thickness falls within such range, a transparent conductive layer having a high light transmittance can be formed.

The length of the metal nanowire is preferably from 2.5 μm to 1,000 μm, more preferably from 10 μm to 500 μm, particularly preferably from 20 μm to 100 μm. When the length falls within such range, a transparent conductive film having high conductivity can be obtained.

Any appropriate metal can be used as a metal constituting the metal nanowire as long as the metal has high conductivity. Examples of the metal constituting the metal nanowire include silver, gold, copper, and nickel. In addition, a material obtained by subjecting any such metal to a plating treatment (such as a gold plating treatment) may be used. Of those, silver, copper, or gold is preferred from the viewpoint of conductivity, and silver is more preferred.

Any appropriate method can be adopted as a method of producing the metal nanowire. Examples thereof include: a method involving reducing silver nitrate in a solution; and a method involving causing an applied voltage or current to act on a precursor surface from the tip portion of a probe, drawing a metal nanowire at the tip portion of the probe, and continuously forming the metal nanowire. In the method involving reducing silver nitrate in the solution, a silver nanowire can be synthesized by performing the liquid-phase reduction of a silver salt such as silver nitrate in the presence of a polyol such as ethylene glycol and polyvinyl pyrrolidone. The mass production of a silver nanowire having a uniform size can be performed in conformity with a method described in, for example, Xia, Y. et al., Chem. Mater. (2002), 14, 4736-4745 or Xia, Y. et al., Nano letters (2003), 3 (37), 955-960.

The transparent conductive layer can be formed by applying, onto the transparent base material, a composition for forming a transparent conductive layer containing the metal nanowire. More specifically, the transparent conductive layer can be formed by applying, onto the transparent base material, a dispersion liquid (composition for forming a transparent conductive layer) obtained by dispersing the metal nanowire in a solvent, and then drying the applied layer.

Examples of the solvent include water, an alcohol-based solvent, a ketone-based solvent, an ether-based solvent, a hydrocarbon-based solvent, and an aromatic solvent. Water is preferably used from the viewpoint of reduction in environmental load.

The dispersion concentration of the metal nanowire in the composition for forming a transparent conductive layer containing the metal nanowire is preferably from 0.1 wt % to 1 wt %. When the dispersion concentration falls within such range, a transparent conductive layer excellent in conductivity and light transmittance can be formed.

The composition for forming a transparent conductive layer containing the metal nanowire may further contain any appropriate additive depending on purposes. Examples of the additive include an anticorrosive material for preventing the corrosion of the metal nanowire and a surfactant for preventing the agglomeration of the metal nanowire. The kinds, number, and amount of additives to be used can be appropriately set depending on purposes. In addition, the composition for forming a transparent conductive layer may contain any appropriate binder resin as required as long as the effects of the present invention are obtained.

Any appropriate method may be adopted as an application method for the composition for forming a transparent conductive layer containing the metal nanowire. Examples of the application method include spray coating, bar coating, roll coating, die coating, inkjet coating, screen coating, dip coating, a relief printing method, an intaglio printing method, and a gravure printing method. Any appropriate drying method (such as natural drying, blast drying, or heat drying) can be adopted as a method of drying the applied layer. In the case of, for example, the heat drying, a drying temperature is typically from 100° C. to 200° C. and a drying time is typically from 1 to 10 minutes.

When the transparent conductive layer contains the metal nanowire, the thickness of the transparent conductive layer is preferably from 0.01 μm to 10 μm, more preferably from 0.05 μm to 3 μm, particularly preferably from 0.1 μm to 1 μm. When the thickness falls within such range, a transparent conductive film excellent in conductivity and light transmittance can be obtained.

When the transparent conductive layer contains the metal nanowire, the total light transmittance of the transparent conductive layer is preferably 85% or more, more preferably 90% or more, still more preferably 95% or more.

The content of the metal nanowire in the transparent conductive layer is preferably from 80 wt % to 100 wt %, more preferably from 85 wt % to 99 wt % with respect to the total weight of the transparent conductive layer. When the content falls within such range, a transparent conductive film excellent in conductivity and light transmittance can be obtained.

When the metal nanowire is a silver nanowire, the density of the transparent conductive layer is preferably from 1.3 g/cm³ to 10.5 g/cm³, more preferably from 1.5 g/cm³ to 3.0 g/cm³. When the density falls within such range, a transparent conductive film excellent in conductivity and light transmittance can be obtained.

(Metal Mesh)

The transparent conductive layer containing the metal mesh is obtained by forming a thin metal wire into a lattice pattern on the transparent base material. The transparent conductive layer containing the metal mesh can be formed by any appropriate method. The transparent conductive layer can be obtained by, for example, applying a photosensitive composition (composition for forming a transparent conductive layer) containing a silver salt onto the transparent base material, and then subjecting the resultant to an exposure treatment and a developing treatment to form the thin metal wire into a predetermined pattern. In addition, the transparent conductive layer can be obtained by printing a paste (composition for forming a transparent conductive layer) containing metal fine particles into a predetermined pattern. Details about such transparent conductive layer and a formation method therefor are described in, for example, JP 2012-18634 A, and the description is incorporated herein by reference. In addition, other examples of the transparent conductive layer constituted of the metal mesh and the formation method therefor are a transparent conductive layer and formation method therefor described in JP 2003-331654 A.

When the transparent conductive layer contains the metal mesh, the thickness of the transparent conductive layer is preferably from 0.1 μm to 30 μm, more preferably from 0.1 μm to 9 μm, still more preferably from 1 μm to 3 μm.

When the transparent conductive layer contains the metal mesh, the transmittance of the transparent conductive layer is preferably 80% or more, more preferably 85% or more, still more preferably 90% or more.

When the transparent conductive film is used in an electrode for a touch panel or the like, the transparent conductive layer may be patterned into a predetermined pattern. The shape of the pattern of the transparent conductive layer is not particularly limited as long as the pattern satisfactorily operates as a touch panel (such as a capacitance-type touch panel). Examples thereof include patterns described in JP 2011-511357 A, JP 2010-164938 A, JP 2008-310550 A, JP 2003-511799 A, and JP 2010-541109 A. After having been formed on the transparent base material, the transparent conductive layer can be patterned by employing a known method.

D. Other Layer

The transparent conductive film may include any appropriate other layer as required. Examples of the other layer include a hard coat layer, an antistatic layer, an antiglare layer, an antireflection layer, and a color filter layer.

The hard coat layer has a function of imparting chemical resistance, scratch resistance, and surface smoothness to the transparent base material.

Any appropriate material can be adopted as a material constituting the hard coat layer. Examples of the material constituting the hard coat layer include an epoxy-based resin, an acrylic resin, and a silicone-based resin, and a mixture thereof. Of those, an epoxy-based resin excellent in heat resistance is preferred. The hard coat layer can be obtained by curing any such resin with heat or an active energy ray.

E. Application

The transparent conductive film can be used in an electronic device such as a display element. More specifically, the transparent conductive film can be used as, for example, an electrode to be used in a touch panel or the like, or an electromagnetic wave shield for blocking an electromagnetic wave responsible for the malfunction of an electronic device.

In one embodiment, a liquid crystal display element can be provided by combining the transparent conductive film and a liquid crystal panel. The liquid crystal display element preferably includes the transparent conductive film and the liquid crystal panel in the stated order from a viewer side.

A more specific example of the liquid crystal display element including the transparent conductive film is a liquid crystal display element illustrated in the schematic sectional view of FIG. 2. A liquid crystal display element 100 of FIG. 2 includes a touch panel 110 including the transparent conductive film of the present invention as an electrode and a liquid crystal panel 120 in the stated order from a viewer side. Any appropriate touch panel can be used as the touch panel, and examples thereof include a resistance film-type touch panel and a capacitance-type touch panel. In one embodiment, like the illustrated example, a touch panel (resistance film-type touch panel) having two transparent conductive films 10 and a spacer 11 placed between the two transparent conductive films 10 can be used. In addition, when the capacitance-type touch panel is used, the transparent conductive layer of the conductive film of the present invention is patterned into a predetermined pattern as described in the section E. Any appropriate liquid crystal panel can be used as the liquid crystal panel. Typically, like the illustrated example, a liquid crystal panel having two polarizing plates 20 and a liquid crystal cell 21 placed between the two polarizing plates can be used. Any appropriate polarizing plates and any appropriate liquid crystal cell can be used as the polarizing plates and the liquid crystal cell, respectively. It should be noted that the touch panel and the liquid crystal panel may each further include any appropriate other member.

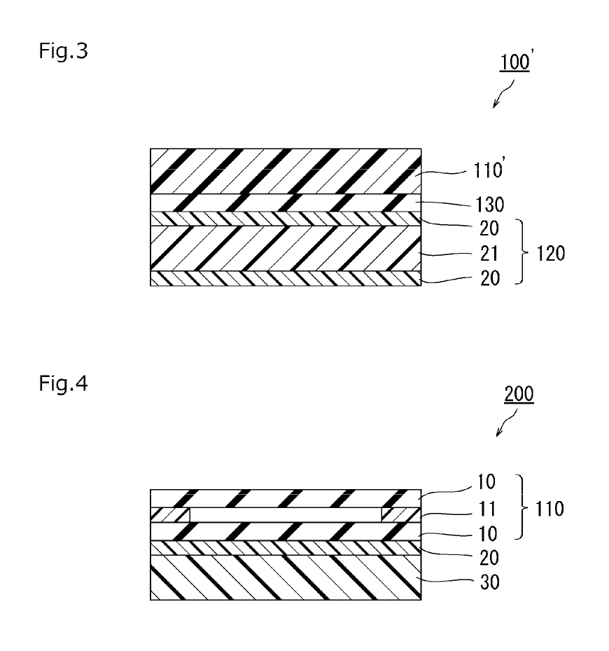

Another specific example of the liquid crystal display element including the transparent conductive film is a liquid crystal display element illustrated in the schematic sectional view of FIG. 3. A liquid crystal display element 100′ of FIG. 3 includes a touch panel 110′, an electromagnetic wave shield 130 constituted of the transparent conductive film 10 of the present invention, and the liquid crystal panel 120 in the stated order from a viewer side.

In the embodiment illustrated in FIG. 3, any appropriate touch panel can be used as the touch panel 110′, and examples thereof include a resistance film-type touch panel and a capacitance-type touch panel. In addition, any appropriate electrode can be used as an electrode to be used in the touch panel 110′. For example, in one embodiment, the transparent conductive film of the present invention is used as the electrode, and in another embodiment, an ITO electrode is used. When the touch panel 110′ is the capacitance-type touch panel, the electrode may be patterned into any appropriate pattern. Examples of the shape of the pattern of the electrode include patterns disclosed in JP 2011-511357 A, JP 2010-164938 A, JP 2008-310550 A, JP 2003-511799 A, and JP 2010-541109 A. It should be noted that any other member (such as a protective sheet) may be placed on the viewer side of the electromagnetic wave shield 130 instead of the touch panel.

In another embodiment, an organic electroluminescence display apparatus can be provided by combining the transparent conductive film, a polarizing plate, and an organic electroluminescence element. The organic electroluminescence display apparatus preferably includes the transparent conductive film, the polarizing plate, and the organic electroluminescence element in the stated order from a viewer side.

A more specific example of the organic electroluminescence display apparatus including the transparent conductive film is an organic electroluminescence display apparatus illustrated in the schematic sectional view of FIG. 4. An organic electroluminescence display apparatus 200 of FIG. 4 includes the touch panel 110 including the transparent conductive film of the present invention as an electrode, the polarizing plate 20, and an organic electroluminescence element 30 in the stated order from a viewer side. Any appropriate touch panel can be used as the touch panel, and examples thereof include a resistance film-type touch panel and a capacitance-type touch panel. In one embodiment, like the illustrated example, a touch panel (resistance film-type touch panel) having the two transparent conductive films 10 and the spacer 11 placed between the two transparent conductive films 10 can be used. In addition, when the capacitance-type touch panel is used, the transparent conductive layer of the conductive film of the present invention is patterned into a predetermined pattern as described in the section E. Any appropriate polarizing plate and any appropriate organic electroluminescence element can be used as the polarizing plate and the organic electroluminescence element, respectively. It should be noted that the organic electroluminescence display apparatus may further include any appropriate other member.

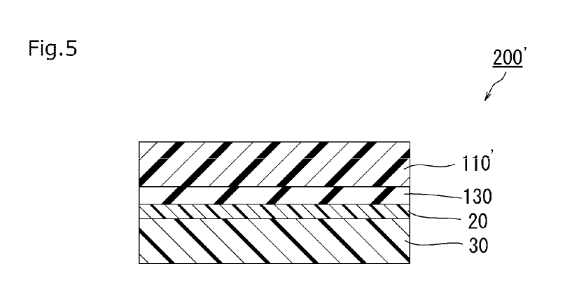

Another specific example of the organic electroluminescence display apparatus including the transparent conductive film is an organic electroluminescence display apparatus illustrated in the schematic view of FIG. 5. An organic electroluminescence display apparatus 200′ of FIG. 5 includes the touch panel 110′, the electromagnetic wave shield 130 constituted of the transparent conductive film 10 of the present invention, the polarizing plate 20, and the organic electroluminescence element 30 in the stated order from a viewer side.

In the embodiment illustrated in FIG. 5, any appropriate touch panel can be used as the touch panel 110′. For example, such touch panel as described in FIG. 3 can be used. In addition, the touch panel may include such electrode as described in FIG. 3. It should be noted that any other member (such as a protective sheet) may be placed on the viewer side of the electromagnetic wave shield 130 instead of the touch panel.

### EXAMPLES

Hereinafter, the present invention is specifically described by way of Examples but the present invention is by no means limited to Examples described below. Evaluation methods in Examples areas described below. It should be noted that a thickness was measured with a Peacock Precision Measuring Instrument Digital Gauge Cordless Type “DG-205” manufactured by Ozaki Mfg Co., Ltd.

(1) Retardation Value

The retardation value of a transparent base material layer was measured with an instrument available under the trade name “KOBRA-WRP” from Oji Scientific Instruments. A measurement temperature was set to 23° C. and a measurement wavelength was set to 545.6 nm.

(2) Surface Resistance Value

The surface resistance value of the resultant transparent conductive film was measured with an instrument available under the trade name “Loresta-GP MCP-T610” from Mitsubishi Chemical Analytech Co., Ltd. by a four-terminal method. A measurement temperature was set to 23° C.

(3) Total Light Transmittance

The total light transmittance of the resultant transparent conductive film was measured with an instrument available under the trade name “HR-100” from Murakami Color Research Laboratory Co., Ltd. at room temperature. It should be noted that the measurement was performed for each film three times and the average of the three measured values was defined as a measured value.

(4) Rainbow Patch Observation

A transparent conductive film was bonded onto a polarizing plate (manufactured by Nitto Denko Corporation, trade name: “NPF-SEG1425DU”) so that the absorption axis of the polarizing plate and the slow axis of a transparent base material were perpendicular to each other. The resultant laminate was placed on a backlight, and the presence or absence of the occurrence of a rainbow patch was observed from an oblique angle of 45° with respect to the slow axis direction of the transparent base material.

### Production Example 1

### Synthesis of Metal Nanowire and Preparation of Composition for Forming Transparent Conductive Layer

5 Milliliters of anhydrous ethylene glycol and 0.5 ml of a solution of PtCl₂ in anhydrous ethylene glycol (concentration: 1.5×10⁻⁴ mol/L) were added to a reaction vessel equipped with a stirring apparatus under 160° C. After a lapse of 4 minutes, 2.5 ml of a solution of AgNO₃ in anhydrous ethylene glycol (concentration: 0.12 mol/1) and 5 ml of a solution of polyvinyl pyrrolidone (MW: 5,500) in anhydrous ethylene glycol (concentration: 0.36 mol/1) were simultaneously dropped to the resultant solution over 6 minutes to produce a silver nanowire. The dropping was performed under 160° C. until AgNO₃ was completely reduced. Next, acetone was added to the reaction mixture containing the silver nanowire obtained as described above until the volume of the reaction mixture became 5 times as large as that before the addition. After that, the reaction mixture was centrifuged (2,000 rpm, 20 minutes). Thus, a silver nanowire was obtained.

The resultant silver nanowire had a short diameter of from 30 nm to 40 nm, a long diameter of from 30 nm to 50 nm, and a length of from 20 μm to 50 μm.

The silver nanowire (concentration: 0.2 wt %) and dodecyl-pentaethylene glycol (concentration: 0.1 wt %) were dispersed in pure water to prepare a composition for forming a transparent conductive layer.

### Example 1

A norbornene-based cycloolefin film (manufactured by Zeon Corporation, trade name: “ZEONOR ZF14”, thickness: 40 μm) was used as a transparent base material. Table 1 shows the thickness direction retardation Rth and in-plane retardation Re of the norbornene-based cycloolefin film.

The surface of the norbornene-based cycloolefin film was hydrophilized by performing a corona treatment. After that, the composition for forming a transparent conductive layer prepared in Production Example 1 was applied onto the film with a bar coater (manufactured by Dai-ichi Rika Co., Ltd., product name: “Bar Coater No. 06”). After that, the composition was dried in a fan dryer at 120° C. for 2 minutes. Thus, a transparent conductive film having a transparent conductive layer (0.1 μm) formed on the transparent base material was obtained.

The resultant transparent conductive film was subjected to the evaluations (2) to (4). Table 1 shows the results.

### Example 2

A transparent conductive film was obtained in the same manner as in Example 1 except that an acrylic polymer film (manufactured by Kaneka Corporation, trade name: “FIX-40UC”) was used instead of the norbornene-based cycloolefin film. The used acrylic polymer film and the resultant transparent conductive film were subjected to the evaluations (1) to (4). Table 1 shows the results.

### Example 3

The surface of the norbornene-based cycloolefin film used in Example 1 was hydrophilized by performing a corona treatment. After that, a metal mesh (line width: 100 μm, lattice having a pitch of 1.5 mm) was formed by using a silver paste (manufactured by Toyochem Co., Ltd., trade name: “RA FS 039”) by a screen printing method, and was sintered at 120° C. for 10 minutes. Thus, a transparent conductive film was obtained.

The resultant transparent conductive film was subjected to the evaluations (2) to (4). Table 1 shows the results.

### Comparative Example 1

A transparent conductive film was obtained in the same manner as in Example 1 except that a PET film (manufactured by Mitsubishi Plastics, Inc., trade name: “DIAFOIL T602”) was used instead of the norbornene-based cycloolefin film. The used PET film and the resultant transparent conductive film were subjected to the evaluations (1) to (4). Table 1 shows the results.

TABLE 1

| | Retardation of | | | | |
|---|---|---|---|---|---|
| | transparent base | | | | |
| | material | | | | |
| | Thickness | | | | |
| | direction | | Surface | | Presence |
| | retardation | In-plane | resistance | Total light | or absence |
| | Rth | retardation | value | transmittance | of rainbow |
| | (nm) | Re (nm) | (Ω/□) | (%) | patch |
| Example 1 | 1.8 | 1.7 | 205 | 91.1 | Absent |
| Example 2 | −0.3 | 0.7 | 223 | 91.2 | Absent |
| Example 3 | 1.8 | 1.7 | 18 | 89.3 | Absent |
| Com- | 6,541 | 1,862 | 219 | 89.3 | Present |
| parative | | | | | |
| Example 1 | | | | | |

As is apparent from Table 1, the transparent conductive film of the present invention has a high light transmittance and high conductivity, and can suppress the occurrence of a rainbow-like patchy pattern.

### INDUSTRIAL APPLICABILITY

The transparent conductive film of the present invention can be used in an electronic device such as a display element. More specifically, the transparent conductive film can be used as, for example, an electrode to be used in a touch panel or the like, or an electromagnetic wave shield.

### REFERENCE SIGNS LIST

1 transparent base material
2 transparent conductive layer
10 transparent conductive film
11 spacer
20 polarizing plate
21 liquid crystal cell
30 organic electroluminescence element
100 liquid crystal display element
200 organic electroluminescence display apparatus

1. A transparent conductive film, comprising:
a transparent base material; and
a transparent conductive layer formed on the transparent base material,
the transparent conductive film having a total light transmittance of 80% or more,
wherein:
the transparent base material has an absolute value of a thickness direction retardation of 100 nm or less; and
the transparent conductive layer contains a metal nanowire or a metal mesh.

2. The transparent conductive film according to claim 1, wherein the thickness direction retardation of the transparent base material is 50 nm or less.

3. The transparent conductive film according to claim 1, wherein the transparent base material has an in-plane retardation of 10 nm or less.

4. The transparent conductive film according to claim 1, wherein the transparent base material contains a cycloolefin-based resin.

5. The transparent conductive film according to claim 1, wherein the transparent base material contains an acrylic resin.

6. The transparent conductive film according to claim 1, wherein the metal nanowire comprises a silver nanowire.

7. A touch panel, comprising the transparent conductive film of claim 1.

8. An electromagnetic wave shield, comprising the transparent conductive film of claim 1.

9. A liquid crystal display element, comprising the touch panel of claim 7.

10. The liquid crystal display element according to claim 9, further comprising an electromagnetic wave shield which comprises the transparent conductive film.

11. The liquid crystal display element, comprising the electromagnetic wave shield of claim 8.

12. An organic electroluminescence display apparatus, comprising the touch panel of claim 7, a polarizing plate, and an organic electroluminescence element in the stated order from a viewer side.

13. The organic electroluminescence display apparatus according to claim 12, further comprising an electromagnetic wave shield which comprises the transparent conductive film between the touch panel and the polarizing plate.

14. An organic electroluminescence display apparatus, comprising the electromagnetic wave shield of claim 8, a polarizing plate, and an organic electroluminescence element in the stated order from a viewer side.
